(19) United States
(12) Patent Application Publication
(10) Pub. No.: US 2025/0324666 A1
(43) Pub. Date: Oct. 16, 2025

(54) THIN-FILM TRANSISTOR AND RADIATION SENSOR

(71) Applicant: Tianma Japan, Ltd., Kawasaki, Kanagawa (JP)

(72) Inventors: Shigeru KIMURA, Kawasaki (JP); Hiroyuki SEKINE, Kawasaki (JP); Takayuki ISHINO, Kawasaki (JP); Koichi IWASA, Kawasaki (JP)

(21) Appl. No.: 19/098,421

(22) Filed: Apr. 2, 2025

(30) Foreign Application Priority Data
Apr. 16, 2024 (JP) 2024-066077
Aug. 22, 2024 (JP) 2024-141051

(51) Int. Cl. H10D 30/67; H10D 64/68; H10F 39/00; H10F 39/18

(52) U.S. Cl. CPC H10D 30/6732; H10D 30/6731; H10D 30/6734; H10D 64/685; H10D 64/693; H10F 39/1892; H10F 39/80373

(57) ABSTRACT

A thin-film transistor to be used for a radiation sensor is disclosed. The thin-film transistor includes a gate electrode, an oxide semiconductor layer, and a gate insulating film located between the oxide semiconductor layer and the gate electrode. The gate insulating film includes a silicon nitride layer, and a silicon oxide layer located between the silicon nitride layer and the oxide semiconductor layer and having interfaces with the silicon nitride layer and the oxide semiconductor layer. The silicon oxide layer has a thickness not less than 1 nm and not more than 4 nm.

### CROSS-REFERENCE TO RELATED APPLICATIONS

This non-provisional application claims priority under 35 U.S.C. § 119 (a) on Patent Application No. 2024-66077 filed in Japan on Apr. 16, 2024 and Patent Application No. 2024-141051 filed in Japan on Aug. 22, 2024, the entire contents of which are hereby incorporated by reference.

### BACKGROUND

This disclosure relates to the structure of a thin-film transistor.

The technology for non-destructively inspecting the inside of a specimen with an image of X-rays transmitted through the specimen is crucial for the field of industrial non-destructive testing. Especially, digital radiography (DR) that directly captures the image of transmitted X-rays as electronic data has become widely employed because of availability of quick image reading and image interpretation assistance through image processing. The DR uses a device called flat panel detector (FPD).

The FPDs used for X-ray sensors are generally categorized as a direct conversion type and an indirect conversion type. The direct conversion type of FPDs directly convert X-rays into an electric signal. The indirect conversion type of FPDs include a luminescent material (scintillator) that converts X-rays into light (such as visible light or ultraviolet light) and a photoelectric conversion element array that converts the light into an electric signal in their X-ray detection panels. An FPD includes arrayed pixels each including a conversion element that converts X-rays or light into an electric signal and a switching thin-film transistor for taking out the electric signal.

### SUMMARY

An aspect of this disclosure is a thin-film transistor to be used for a radiation sensor. The thin-film transistor includes a gate electrode, an oxide semiconductor layer, and a gate insulating film located between the oxide semiconductor layer and the gate electrode. The gate insulating film includes a silicon nitride layer, and a silicon oxide layer located between the silicon nitride layer and the oxide semiconductor layer and having interfaces with the silicon nitride layer and the oxide semiconductor layer. The silicon oxide layer has a thickness not less than 1 nm and not more than 4 nm.

An aspect of this disclosure is a thin-film transistor to be used for a radiation sensor. The thin-film transistor includes a gate electrode, an oxide semiconductor layer, and a gate insulating film located between the oxide semiconductor layer and the gate electrode. The gate insulating film includes a silicon nitride layer, and a silicon oxynitride layer located between the silicon nitride layer and the oxide semiconductor layer and having interfaces with the silicon nitride layer and the oxide semiconductor layer. The silicon oxynitride layer has a thickness not less than 1 nm and not more than 3 nm.

An aspect of this disclosure is a thin-film transistor to be used for a radiation sensor. The thin-film transistor includes a gate electrode, an oxide semiconductor layer, and a gate insulating film located between the oxide semiconductor layer and the gate electrode. The gate insulating film includes a silicon nitride layer, and a silicon oxynitride layer located between the silicon nitride layer and the oxide semiconductor layer and having interfaces with the silicon nitride layer and the oxide semiconductor layer. The silicon oxynitride layer has a nitrogen atomic ratio lower than a silicon atomic ratio.

It is to be understood that both the foregoing general description and the following detailed description are exemplary and explanatory and are not restrictive of this disclosure.

### BRIEF DESCRIPTION OF THE DRAWINGS

FIG. 1 is a block diagram illustrating a configuration example of an X-ray sensor.

FIG. 2 is a circuit diagram illustrating a configuration example of an equivalent circuit of a pixel.

FIG. 3 illustrates a cross-sectional structure of a pixel.

FIG. 4 is a plan diagram of a pixel.

FIG. 5 is a cross-sectional diagram schematically illustrating the structure of a thin-film transistor in an embodiment of this specification.

FIG. 6 provides a plurality of graphs showing the relation between the change in current-voltage characteristic caused by gate voltage application to an oxide semiconductor thin-film transistor and the thickness of a silicon oxide film.

FIG. 7 provides a plurality of graphs showing the relation between the change in current-voltage characteristic caused by X-ray irradiation to an oxide semiconductor thin-film transistor and the thickness of a silicon oxide film.

FIG. 8 is a graph in which the measurement results in FIGS. 6 and 7 are consolidated.

FIG. 9 provides a plurality of graphs showing the relation between the change in current-voltage characteristic caused by gate voltage application to an oxide semiconductor thin-film transistor and the thickness of a silicon oxynitride film.

FIG. 10 provides a plurality of graphs showing the relation between the change in current-voltage characteristic caused by X-ray irradiation to an oxide semiconductor thin-film transistor and the thickness of a silicon oxynitride film.

FIG. 11 is a graph in which the measurement results in FIGS. 9 and 10 are consolidated.

FIG. 12A illustrates the change in a characteristic of an oxide semiconductor transistor including an electron blocking layer made of a silicon oxynitride film having a first composition ratio between before and after gate voltage application.

FIG. 12B illustrates the change in the characteristic of an oxide semiconductor transistor including an electron blocking layer made of a silicon oxynitride film having the first composition ratio between before and after X-ray irradiation.

FIG. 13A illustrates the change in the characteristic of an oxide semiconductor transistor including an electron blocking layer made of a silicon oxynitride film having a second composition ratio between before and after gate voltage application.

FIG. 13B illustrates the change in the characteristic of an oxide semiconductor transistor including an electron blocking layer made of a silicon oxynitride film having the second composition ratio between before and after X-ray irradiation.

FIG. 14 provides results of composition analysis of an oxide semiconductor transistor including an electron blocking layer having the first composition ratio and an oxide semiconductor transistor including an electron blocking layer having the second composition ratio.

FIG. 15 is a cross-sectional diagram schematically illustrating a structural example of a switching thin-film transistor in an X-ray sensor in an embodiment of this specification.

FIG. 16 is a cross-sectional diagram illustrating a structural example of a switching thin-film transistor having a top-gate structure.

FIG. 17 is a cross-sectional diagram illustrating a structural example of a switching thin-film transistor having a dual-gate structure.

### EMBODIMENTS

Hereinafter, embodiments are described with reference to the accompanying drawings. The embodiments are merely examples to implement this disclosure and are not to limit the technical scope of this disclosure. Some elements in the drawings may be exaggerated in size or shape for clear understanding of description.

An embodiment of this specification discloses a structure of an oxide semiconductor thin-film transistor applicable to a radiation sensor. Radiation sensors including an oxide semiconductor thin-film transistor having a high driving capability have been developed actively. However, the oxide semiconductor thin-film transistor may significantly vary in its threshold voltage and work incorrectly when it is irradiated with radioactive rays, particularly X-rays. This problem is remarkable in the industrial field where the transistor is irradiated with a high dose of X-rays, compared to the medical field that uses a low dose of X-rays.

To improve the resistance to radioactive rays of the oxide semiconductor thin-film transistor, the inventors found a solution of employing silicon nitride (SiNx) for the gate insulating film. However, another problem was found that the oxide semiconductor thin-film transistor having a silicon nitride gate insulating film shows a threshold voltage shift when electrons are induced in the channel by gate voltage application.

An embodiment of this specification provides a gate insulating film consisting of a plurality of layers of different materials in which an electron blocking layer is disposed between the silicon nitride film and the oxide semiconductor film. The electron blocking layer is in direct contact with each of the silicon nitride film and the oxide semiconductor film and has interfaces with them. The electron blocking layer can be a silicon oxide film or a silicon oxynitride film. The electron blocking layer reduces the threshold voltage shift caused by inducing electrons in the channel.

In the following, an X-ray sensor is described by way of example; however, the features of the disclosure herein are applicable to sensors for radioactive rays different from X-rays.

### FIRST EMBODIMENT

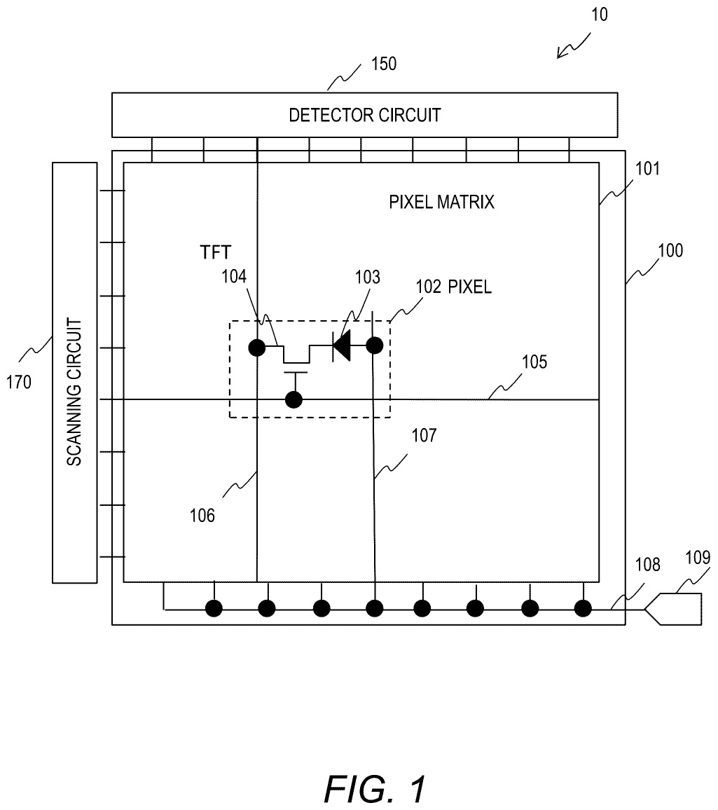

FIG. 1 is a block diagram illustrating a configuration example of an X-ray sensor. The X-ray sensor 10 is an image sensor for imaging X-rays transmitted through an object. The X-ray sensor 10 includes a pixel matrix 101, a scanning circuit 170, and a detector circuit 150. The pixel matrix 101 includes pixels 102 arrayed in a matrix. The pixel matrix 101 is fabricated on a sensor substrate 100. The sensor substrate 100 is a substrate having insulating properties (e.g., a glass substrate).

The pixels 102 are disposed at intersections between a plurality of signal lines 106 and a plurality of gate lines (scanning lines) 105. In FIG. 1, the signal lines 106 are disposed to extend vertically and be horizontally distant from one another and the gate lines 105 are disposed to extend horizontally and be vertically distant from one another. Each pixel 102 is connected to a bias line 107. In FIG. 1, a plurality of bias lines 107 are disposed to extend vertically and be horizontally distant from one another. In FIG. 1, only one of the pixels, one of the signal lines, one of the gate lines, and one of the bias lines are provided with reference signs 102, 106, 105, and 107, respectively.

Each signal line 106 is connected to a different pixel column. Each gate line 105 is connected to a different pixel row. The signal line 106 is connected to the detector circuit 150 and the gate line 105 is connected to the scanning circuit 170. Each bias line 107 is connected to a common bias line 108. A bias potential is supplied to a pad 109 of the common bias line 108.

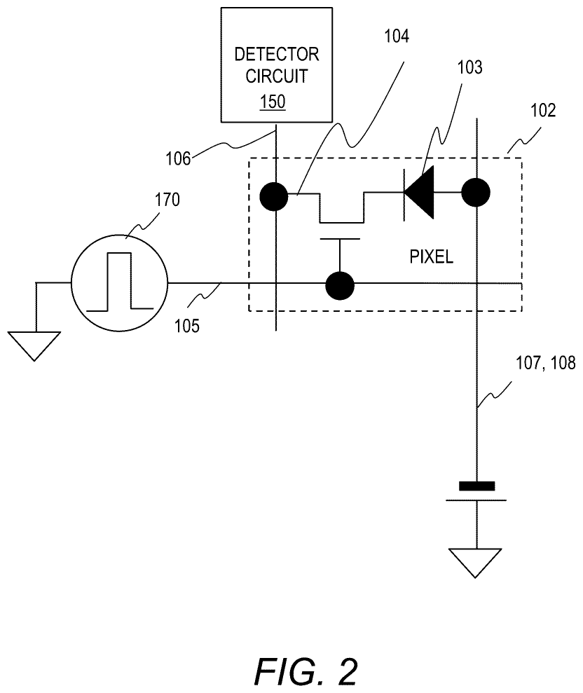

FIG. 2 is a circuit diagram illustrating a configuration example of an equivalent circuit of a pixel 102. The pixel 102 includes a photodiode 103 of a photoelectric conversion element and a thin-film transistor (TFT) 104 of a switching element. In the thin-film transistor 104, the gate is connected to a gate line 105; one source/drain is connected to a signal line 106; and the other source/drain is connected to the cathode of the photodiode 103. In the example of FIG. 2, the anode of the photodiode 103 is connected to a bias line 107.

The thin-film transistor 104 can be an oxide semiconductor thin-film transistor. The thin-film transistor 104 in the configuration example of FIG. 2 has an n-type of conductivity. The thin-film transistor 104 can have a different conductivity. The oxide semiconductor thin-film transistor exhibits a good switching characteristic.

The X-ray sensor 10 reads a signal of a pixel 102 by taking out signal charge stored in proportion to the amount of X-ray irradiation from the photodiode 103 to the external. The signal charge can be taken out by making the thin-film transistor 104 in the pixel 102 conductive. Specifically, when light enters the photodiode 103, signal charge is generated and stored in the photodiode 103.

The scanning circuit 170 selects gate lines 105 one by one to apply a pulse to make the thin-film transistor 104 conductive. The anode terminal of the photodiode 103 is connected to a bias line 107 and the signal line 106 is supplied with a reference potential by the detector circuit 150. Accordingly, the photodiode 103 is charged with a difference voltage between the bias potential of the bias line 107 and the reference potential. This difference voltage is determined so that the cathode potential is higher than the anode potential to reverse-bias the photodiode 103.

The charge required to recharge the photodiode 103 to the reverse bias voltage depend on the amount of light incident on the photodiode 103. The detector circuit 150 reads the signal charge by integrating the current that flows until the photodiode 103 is recharged to the reverse bias voltage.

The charge stored in the photodiode 103 inevitably decreases because of incident light and dark leakage current that flows even when the photodiode 103 is not irradiated with light. Accordingly, in the thin-film transistor 104 under the operation of signal charge reading, the voltage at the terminal connected to the signal line 106 is equal to or higher than the voltage at the terminal connected to the photodiode 103. That is to say, the terminal connected to the signal line 106 is the drain and the terminal connected to the photodiode 103 is the source in detecting signal charge.

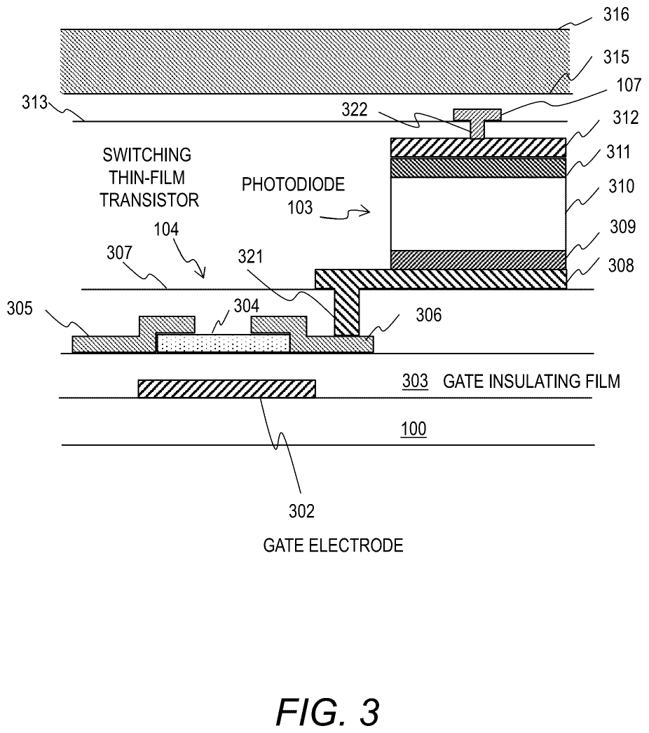

FIG. 3 illustrates a cross-sectional structure of a pixel. In the following description, the side opposite the sensor substrate 100 with respect to the photodiode 103 in FIG. 3 is defined as front. In the positional relations of the components of a pixel, the side closer to the sensor substrate 100 is referred to as lower side and the opposite side as upper side.

The thin-film transistor 104 and the photodiode 103 included in a pixel each have a layered structure. The thin-film transistor 104 includes a gate electrode 302 provided above a sensor substrate 100 having insulating properties, a gate insulating film 303 above the gate electrode 302, and an oxide semiconductor layer 304 above the gate insulating film 303.

The thin-film transistor 104 in FIG. 3 has a bottom-gate structure; the gate electrode 302 is located under the oxide semiconductor layer 304. The thin-film transistor 104 further includes a source/drain electrode 305 and another source/drain electrode 306 above the gate insulating film 303. The source/drain electrodes 305 and 306 are individually connected to the oxide semiconductor layer 304. Each of the source/drain electrodes 305 and 306 is in contact with a side face and a part of the top face of the island-like oxide semiconductor layer 304.

In detecting the charge of the photodiode 103, the electrode 305 is a drain electrode and the electrode 306 is a source electrode.

The gate insulating film 303 is provided to cover the entire gate electrode 302. The gate insulating film 303 is provided between the gate electrode 302 and the oxide semiconductor layer 304, between the gate electrode 302 and the source/drain electrode 305, and between the gate electrode 302 and the source/drain electrode 306.

A first interlayer insulating film 307 is provided to cover the entire thin-film transistor 104. Specifically, the first interlayer insulating film 307 covers the top face of the oxide semiconductor layer 304 and the top faces of the source/drain electrodes 305 and 306.

The sensor substrate 100 can be made of glass or resin. The gate electrode 302 is a conductor and can be made of a metal or impurity-doped silicon. The gate insulating film 303 has a multilayer structure. Each layer of the gate insulating film 303 can be made of silicon oxide (SiOx), silicon nitride (SiNx), or silicon oxynitride (SiOxNy). The details of the gate insulating film 303 will be described later.

The oxide semiconductor for the oxide semiconductor layer 304 is an oxide semiconductor including at least one of In, Ga, and Zn, such as IGZO. Examples of IGZO include amorphous InGaZnO (a-InGaZnO) and microcrystalline InGaZnO. Other oxide semiconductors such as a-InSnZnO and a-InGaZnSnO can also be employed. The examples described in the following principally employ amorphous or microcrystalline InGaZnO (which can also be expressed simply as IGZO in the following).

The source/drain electrodes 305 and 306 are conductors and can be made of a metal such as Mo, Ti, Al, or Cr, an alloy thereof, or a laminate of these metals or alloys. The first interlayer insulating film 307 is an inorganic or organic insulator. Although the thin-film transistor 104 in FIG. 3 has a bottom-gate structure, the thin-film transistor 104 can have a top-gate structure or a dual-gate structure. The dual-gate structure has a top gate and a bottom gate; the bottom-gate structure has a bottom gate only; and the top-gate structure has a top gate only.

The photodiode 103 is fabricated above the first interlayer insulating film 307. The example of the photodiode 103 in FIG. 3 is a PIN diode. The PIN diode has a thick depletion layer in the film thickness to enable efficient light detection. The photodiode 103 includes layered semiconductors sandwiched between a lower electrode 308 above the first interlayer insulating film 307 and an upper electrode 312. The lower electrode 308 is connected to the source/drain electrode 306 of the thin-film transistor 104 through an interconnection region in a via hole 321 of the first interlayer insulating film 307.

The lower electrode 308 is a conductor and can be made of a metal such as Cr, Mo, or Al, an alloy thereof, or a laminate of these metals or alloys. The upper electrode 312 is a transparent electrode that transmits light from a scintillator 316 and can be made of ITO, for example.

The photodiode 103 includes an n-type amorphous silicon layer 309 above the lower electrode 308, an intrinsic amorphous silicon layer 310 above the n-type amorphous silicon layer 309, and a p-type amorphous silicon layer 311 above the intrinsic amorphous silicon layer 310. The upper electrode 312 is provided above the p-type amorphous silicon layer 311. The light to be detected enters the photodiode 103 from above the upper electrode 312 (the p-type amorphous silicon layer 311).

A second interlayer insulating film 313 is provided to cover the photodiode 103. Specifically, the second interlayer insulating film 313 is provided above the first interlayer insulating film 307, a part of the lower electrode 308, and the upper electrode 312. The second interlayer insulating film 313 is an inorganic or organic insulator.

A bias line 107 is provided above the second interlayer insulating film 313. The bias line 107 is connected to the upper electrode 312 through an interconnection region provided in a via hole 322 of the second interlayer insulating film 313. The bias line 107 is a conductor and can be made of a metal such as Mo, Ti, or Al, an alloy thereof, or a laminate of these metals or alloys.

A passivation layer 315 is provided to cover the bias line 107 and the second interlayer insulating film 313. The passivation layer 315 covers the entire pixel matrix 101. The passivation layer 315 is an inorganic or organic insulator. A scintillator 316 is provided above the passivation layer 315.

The scintillator 316 covers the entire pixel matrix 101. The scintillator 316 converts received X-rays into light having a wavelength detectable for the photodiode 103. The photodiode 103 stores signal charge in the amount depending on the light from the scintillator 316.

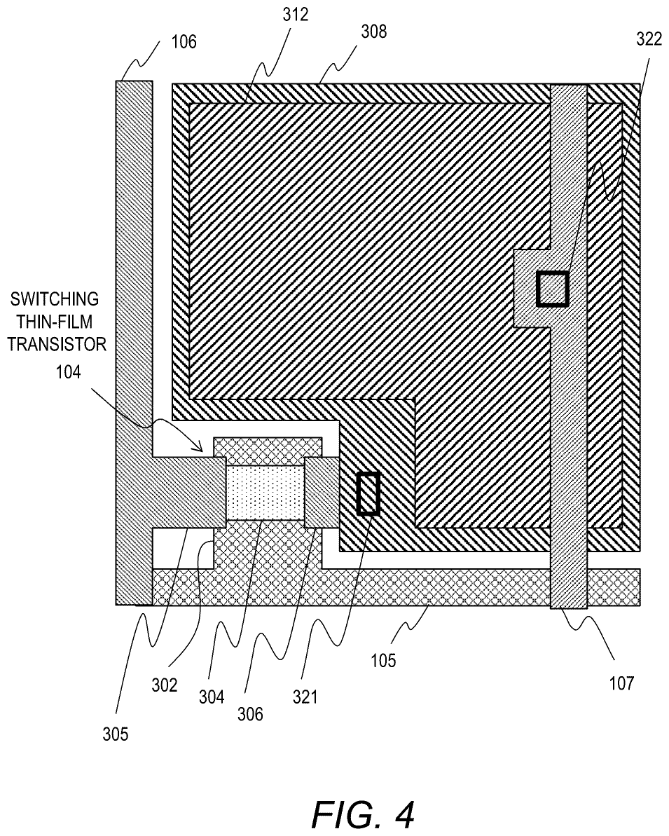

FIG. 4 is a plan diagram of a pixel 102. As illustrated in FIG. 4, a gate line 105 extends from the left to the right of FIG. 4 and a signal line 106 extends from the top to the bottom of FIG. 4. The gate electrode 302 is unseparated from the gate line 105; these are parts of an unseparated metal film. The gate electrode 302 is projecting from the gate line 105 perpendicularly to the direction in which the gate line 105 extends.

The source/drain electrode 305 of the thin-film transistor is unseparated from the signal line 106; these are parts of an unseparated metal film. The source/drain electrode 305 is projecting from the signal line 106 perpendicularly to the direction in which the signal line 106 extends. The source/drain electrode 306 is an island-like electrode and is distant from the source/drain electrode 305.

The oxide semiconductor layer 304 is disposed to overlap the gate electrode 302, when viewed planarly. The source/drain electrode 305 is disposed on one side of the oxide semiconductor layer 304 and the source/drain electrode 306 is disposed on the opposite side. The source/drain electrode 306 is partially covered with the lower electrode 308 of the photodiode 103 and is connected to the lower electrode 308 through a via hole 321.

When the example of FIG. 4 is viewed planarly, the entire upper electrode 312 of the photodiode 103 is within the region of the lower electrode 308. A bias line 107 extends from the bottom to the top of FIG. 4. The bias line 107 overlaps the upper electrode 312 and is connected to the upper electrode 312 through a via hole 322.

Although the configuration example described with reference to FIGS. 1 to 4 includes a photodiode as an element for converting radioactive rays to an electric signal, other kinds of elements can be employed. For example, an element that can directly convert X-rays to an electric signal without a scintillator can be employed.

A feature of an embodiment of this specification is in the structure of a switching thin-film transistor in each pixel of a radiation sensor. Hereinafter, structures of a thin-film transistor related to some embodiments of this specification The inventors' research revealed that the structure of the gate are described. insulating film in the switching thin-film transistor affects the characteristics of the switching thin-film transistor being irradiated with radioactive rays, particularly X-rays.

Specifically, in the case where the gate insulating film is made of a single silicon oxide (SiOx) layer, the threshold voltage Vth of the thin-film transistor shifts negatively in response to irradiation with X-rays, so that correct operation could become difficult. This is inferred because the holes generated in response to the X-ray irradiation get trapped in the silicon oxide layer and negatively shift the threshold voltage Vth.

In the case where the gate insulating film is made of a single silicon nitride (SiNx) layer, the threshold voltage Vth of the thin-film transistor shifts positively in response to application of a positive voltage to the gate electrode of the thin-film transistor. This is inferred because the electrons in the oxide semiconductor layer induced by the voltage application to the gate electrode move to and get trapped in the silicon nitride layer.

An embodiment of this specification includes a gate insulating film consisting of a plurality of layers, in which a silicon oxide film (silicon oxide layer) or a silicon oxynitride (SiOxNy) film (silicon oxynitride layer) is disposed between a silicon nitride film (silicon nitride layer) and the gate electrode. The silicon oxide film or silicon oxynitride film is in direct contact with the silicon nitride layer and the gate electrode and has interfaces with them.

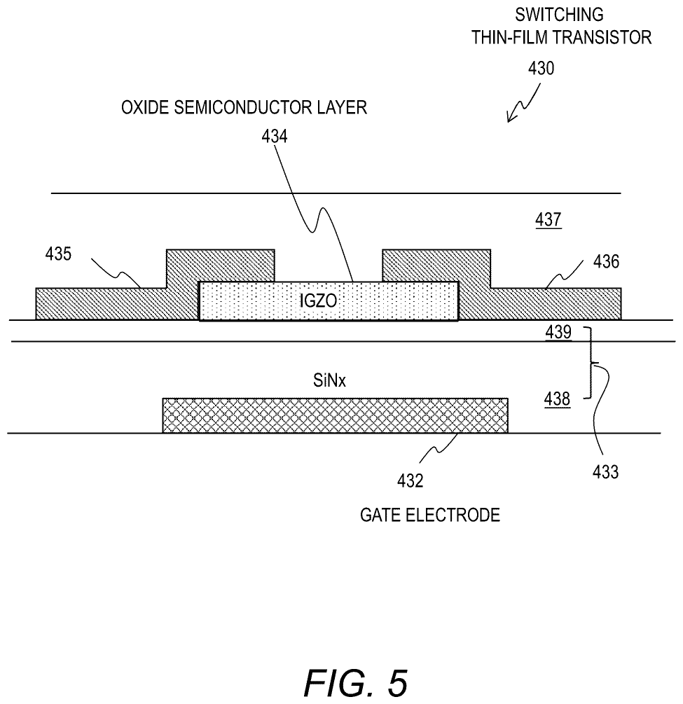

FIG. 5 is a cross-sectional diagram schematically illustrating the structure of a switching thin-film transistor in an embodiment of this specification. The switching thin-film transistor 430 includes a gate electrode 432, a gate insulating film 433 above the gate electrode 432, and an oxide semiconductor layer 434 above the gate insulating film 433. The oxide semiconductor layer 434 is made of IGZO. The entire thin-film transistor 430 is covered with an interlayer insulating layer 437.

The gate insulating film 433 has a two-layer structure consisting of a silicon nitride film (silicon nitride layer) 438 made of silicon nitride (SiNx) and an insulating film 439 made of silicon oxide (SiOx) above the silicon nitride film 438.

The thin-film transistor 430 has a bottom-gate structure; the gate electrode 432 is located under the oxide semiconductor layer 434 (on the side closer to the substrate). The thin-film transistor 430 further includes a source/drain electrode 435 and another source/drain electrode 436 above the gate insulating film 433. The source/drain electrodes 435 and 436 are individually connected to the oxide semiconductor layer 434. Although the thin-film transistor 430 in this embodiment is of a channel etch type, it can be of a channel protection type such that the channel region of the oxide semiconductor layer 434 is protected with an insulating film.

The silicon oxide film 439 is thinner than the silicon nitride film 438. The silicon oxide film 439 in an embodiment of this specification has a thickness of not less than 1 nm and not more than 4 nm. The silicon nitride film 438 can have a thickness of several-hundred nanometers, or between 100 nm and 900 nm.

Application of a voltage to the gate electrode may cause electrons to be injected from the oxide semiconductor layer to the silicon nitride film. The silicon oxide film 439 between the silicon nitride film 438 and the oxide semiconductor layer 434 is an electron blocking layer that blocks (suppresses) the movement of the electrons from the oxide semiconductor layer 434 to the silicon nitride film 438.

Disposing a silicon oxide film between the oxide semiconductor layer and the silicon nitride film reduces the change in characteristics of the oxide semiconductor thin-film transistor caused by the carriers trapped in the silicon nitride film because of the operation of the oxide semiconductor thin-film transistor (the application of the gate voltage).

The silicon oxide film can effectively block the movement of electrons from the oxide semiconductor layer to the silicon nitride film by having a thickness larger than a specific value. The inventors' research revealed that a silicon oxide film having a thickness of 1 nm or more can effectively stabilize the characteristics of an oxide semiconductor thin-film transistor.

However, carriers generated and trapped in the silicon oxide film of a constituent of the electron blocking layer by being irradiated with radioactive rays, particularly X-rays, may significantly affect the threshold voltage Vth of the oxide semiconductor layer directly above the silicon oxide film. This effect onto the threshold voltage Vth can be effectively reduced by thinning the silicon oxide film.

The inventors' research revealed that a silicon oxide film having a thickness of 4 nm or less can effectively reduce the effect onto the threshold voltage Vth to make the oxide semiconductor thin-film transistor work stably as a switching thin-film transistor. Particularly, the stability of the switching thin-film transistor can be maintained under irradiation with strong X-rays, for example, 500 Gy or more of X-rays.

As described above, disposing the silicon oxide film between the silicon nitride film and the oxide semiconductor layer prevents movement of electrons from the oxide semiconductor layer to the silicon nitride film and thinning the silicon oxide film eliminates the effect of holes trapped in the silicon oxide film. As a result, a thin-film transistor having radiation resistance and stable characteristics can be provided.

In the following, some measurement results on oxide semiconductor thin-film transistors including silicon oxide films having different thicknesses are described.

The oxide semiconductor thin-film transistors used in the measurement had the structure illustrated in FIG. 5; their insulating films 439 were made of silicon oxide and their oxide semiconductor layers 434 were made of IGZO.

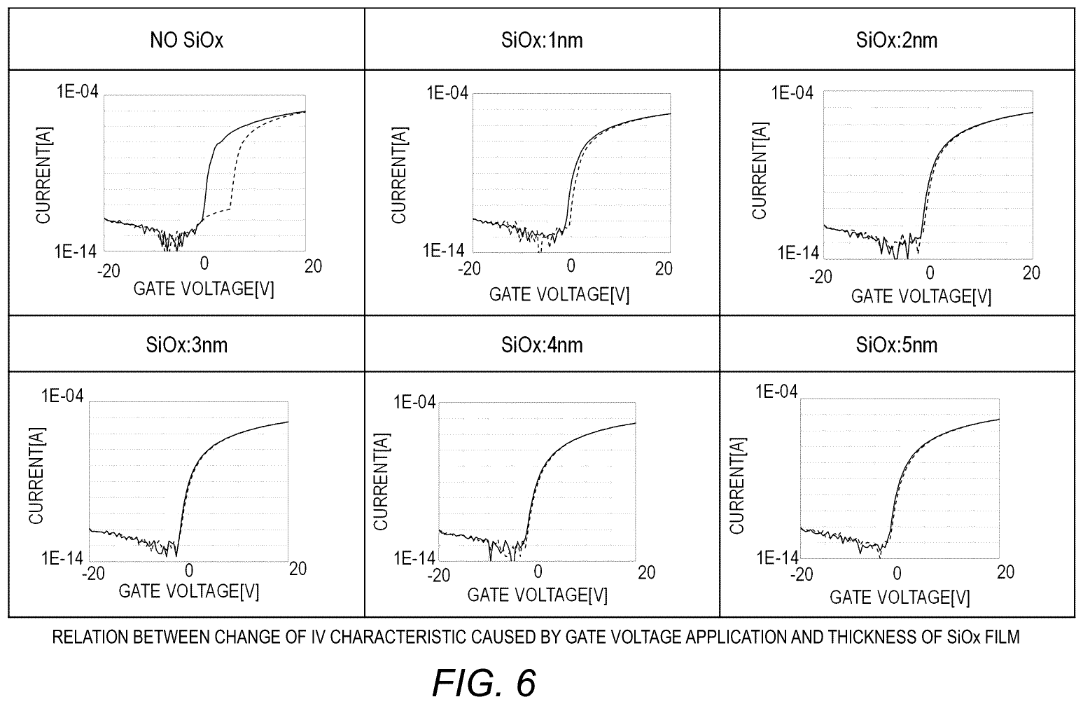

First, the effect to block the movement of electrons from the oxide semiconductor layer to the silicon nitride film is described. FIG. 6 provides a plurality of graphs showing the relation between the change in IV (current-voltage) characteristic caused by gate voltage application to an oxide semiconductor thin-film transistor and the thickness of a silicon oxide (SiOx) film. Specifically, the graphs are measurement results on oxide semiconductor thin-film transistors including silicon oxide films having thicknesses of 0 nm (no SiOx), 1 nm, 2 nm, 3 nm, 4 nm, and 5 nm. Each graph is a result of measuring the drain current in response to sweep of gate voltage. In the measurement, radioactive rays were not emitted. In each graph, the horizontal axis represents the gate voltage and the vertical axis represents the drain current. In each graph, the solid line indicates the first measurement result and the broken line indicates the second measurement result.

As understood from the graphs in FIG. 6, the oxide semiconductor thin-film transistor without silicon oxide (no SiOx) shows a big change in threshold voltage between the first measurement result and the second measurement result. However, the oxide semiconductor thin-film transistors with a silicon oxide film having a thickness of 1 nm or more (SiOx: 1nm, SiOx: 2 nm, SiOx: 3 nm, SiOx: 4 nm, and SiOx: 5 nm) show small changes in threshold voltage, which are within the range substantially not to affect the operation of the oxide semiconductor transistor.

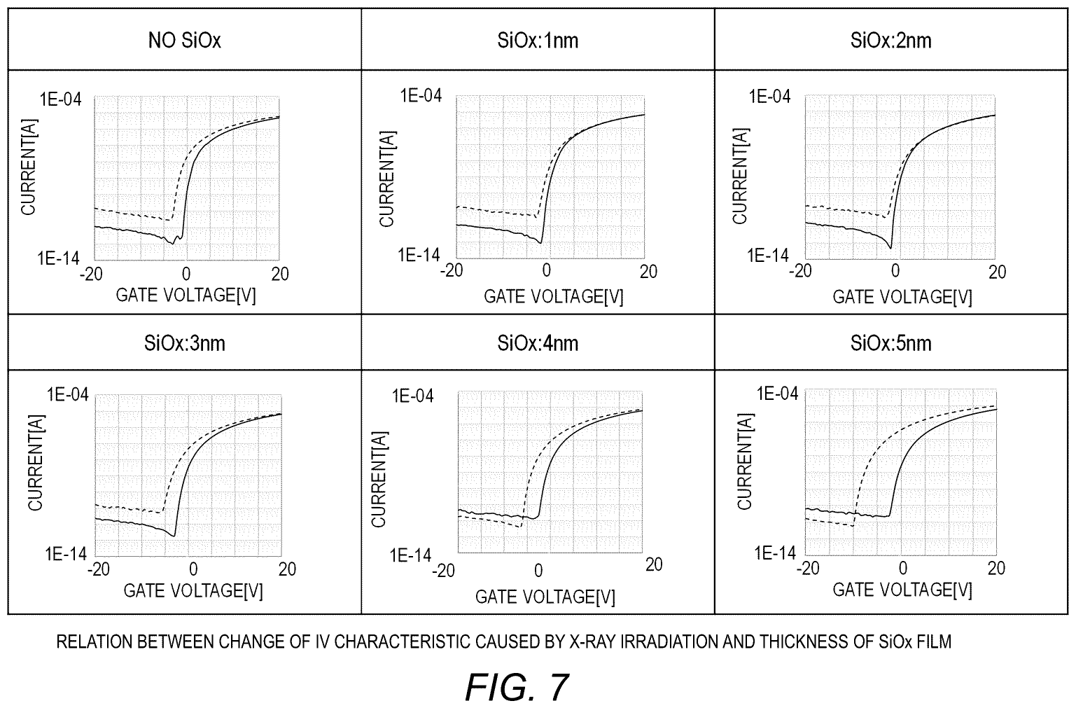

Next, the effect of the electron blocking layer to the IV characteristic of the oxide semiconductor thin-film transistor irradiated with X-rays is described. FIG. 7 provides a plurality of graphs showing the relation between the change in IV (current-voltage) characteristic caused by X-ray irradiation to an oxide semiconductor thin-film transistor and the thickness of a silicon oxide (SiOx) film.

Specifically, the graphs are measurement results on oxide semiconductor thin-film transistors including silicon oxide films having thicknesses of 0 nm (no SiOx), 1nm, 2 nm, 3 nm, 4 nm, and 5 nm. Each graph is a result of measuring the drain current in response to sweep of gate voltage. In each graph, the horizontal axis represents the gate voltage and the vertical axis represents the drain current. In each graph, the solid line indicates the measurement result before being irradiated with X-rays and the broken line indicates the measurement result after being irradiated with X-rays. The dose of X-rays was 660 Gy.

As understood from the graphs in FIG. 7, the oxide semiconductor thin-film transistor including a silicon oxide film having a thickness of 5 nm (SiOx: 5 nm) shows a big change in threshold voltage between the measurement results before and after X-ray irradiation. However, the oxide semiconductor thin-film transistors including a silicon oxide film having a thickness of 4 nm or less (No SiOx, SiOx: 1nm, SiOx: 2 nm, SiOx: 3 nm, and SiOx: 4 nm) show small changes in threshold voltage, which are within the range substantially not to affect the operation of the oxide semiconductor transistor.

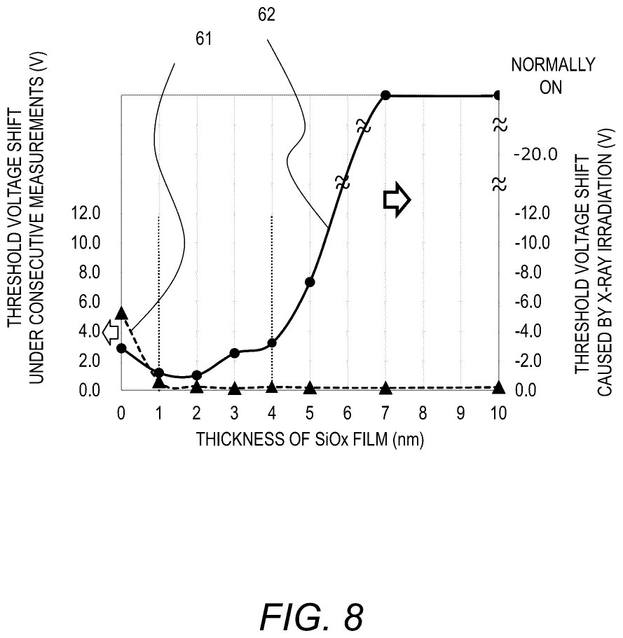

FIG. 8 is a graph in which the measurement results in FIGS. 6 and 7 are consolidated. The horizontal axis represents the thickness of the silicon oxide film. The left vertical axis represents the amount of the threshold voltage shift caused by application of gate voltage described with reference to FIG. 6. The right vertical axis represents the amount of the threshold voltage shift caused by X-ray irradiation described with reference to FIG. 7. The broken line 61 represents the variation in the amount of threshold voltage shift caused by the application of gate voltage and the solid line 62 represents the variation in the amount of threshold voltage shift caused by the X-ray irradiation.

As understood from the measurement results in FIGS. 6 to 8, a silicon oxide film having a thickness in the range from 1 nm to 4 nm can suppress the threshold voltage shift caused by gate voltage application and X-ray irradiation to the level that substantially does not affect the operation of the oxide semiconductor transistor.

Next, the thickness of a silicon oxynitride film used in place of the silicon oxide film 439 is discussed. In the following, some measurement results on oxide semiconductor thin-film transistors including silicon oxynitride films having different thicknesses are described. The oxide semiconductor thin-film transistors used in the measurement had the structure illustrated in FIG. 5; their insulating films 439 were made of silicon oxynitride and their oxide semiconductor layers 434 were made of IGZO.

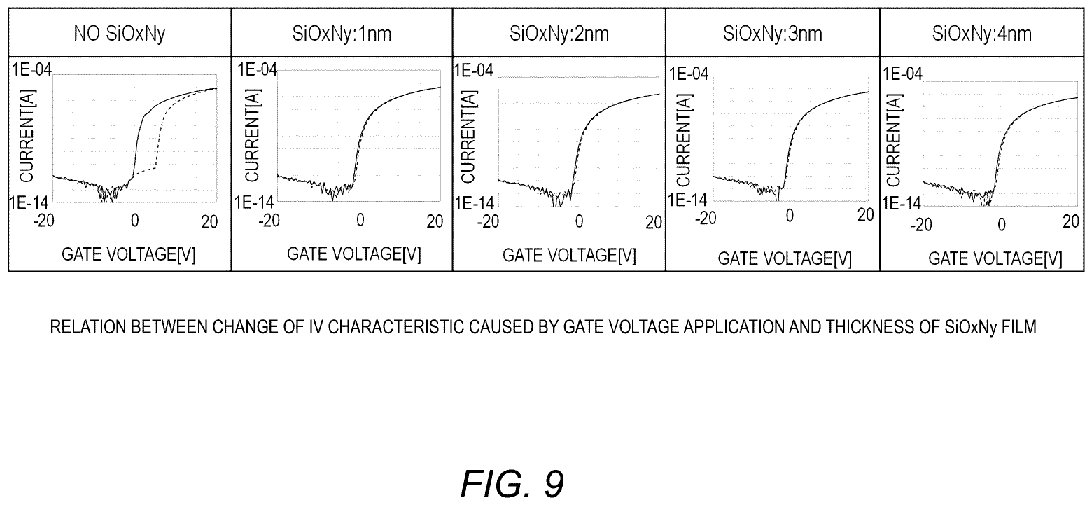

First, the effect to block the movement of electrons from the oxide semiconductor layer to the silicon nitride film is described. FIG. 9 provides a plurality of graphs showing the relation between the change in IV (current-voltage) characteristic caused by gate voltage application to the oxide semiconductor thin-film transistor and the thickness of a silicon oxynitride film. Specifically, the graphs are measurement results on oxide semiconductor thin-film transistors including silicon oxynitride films having thicknesses of 0 nm (no SiOxNy), 1 nm, 2 nm, 3 nm, and 4 nm. Each graph is a result of measuring the drain current in response to sweep of gate voltage. In the measurement, radioactive rays were not emitted. In each graph, the horizontal axis represents the gate voltage and the vertical axis represents the drain current. In each graph, the solid line indicates the first measurement result and the broken line indicates the second measurement result.

As understood from the graphs in FIG. 9, the oxide semiconductor thin-film transistor without silicon oxynitride (no SiOxNy) shows a big change in threshold voltage between the first measurement result and the second measurement result.

However, the oxide semiconductor thin-film transistors with a silicon oxynitride film having a thickness of 1 nm or more (SiOxNy: 1 nm, SiOxNy: 2 nm, SiOxNy: 3 nm, and SiOxNy: 4 nm) show small changes in threshold voltage, which are within the range substantially not to affect the operation of the oxide semiconductor transistor.

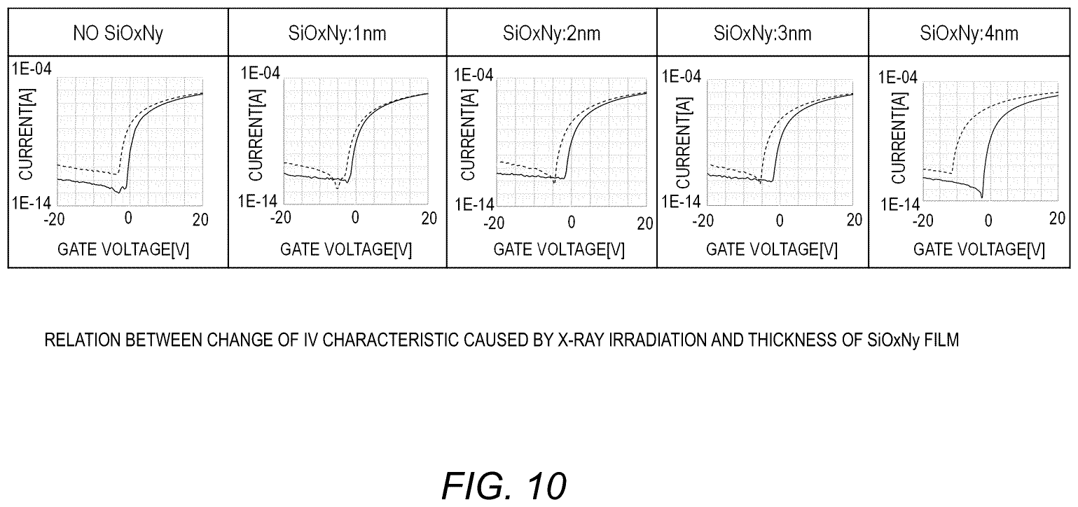

Next, the effect of the electron blocking layer to the IV characteristic of the oxide semiconductor thin-film transistor irradiated with X-rays is described. FIG. 10 provides a plurality of graphs showing the relation between the change in IV (current-voltage) characteristic caused by X-ray irradiation to an oxide semiconductor thin-film transistor and the thickness of the silicon oxynitride (SiOxNy) film.

Specifically, the graphs are measurement results on oxide semiconductor thin-

film transistors including silicon oxynitride films having thicknesses of 0 nm (no SiOxNy), 1 nm, 2 nm, 3 nm, and 4 nm. Each graph is a result of measuring the drain current in response to sweep of gate voltage. In each graph, the horizontal axis represents the gate voltage and the vertical axis represents the drain current. In each graph, the solid line indicates the measurement result before being irradiated with X-rays and the broken line indicates the measurement result after being irradiated with X-rays. The dose of X-rays was 660 Gy.

As understood from the graphs in FIG. 10, the oxide semiconductor thin-film transistor including a silicon oxynitride film having a thickness of 4 nm (SiOxNy: 4 nm) shows a big change in threshold voltage between the measurement results before and after X-ray irradiation. However, the oxide semiconductor thin-film transistors including a silicon oxynitride film having a thickness of 3 nm or less (No SiOxNy, SiOxNy: 1nm, SiOxNy: 2 nm, and SiOxNy: 3 nm) show small changes in threshold voltage, which are within the range substantially not to affect the operation of the oxide semiconductor transistor.

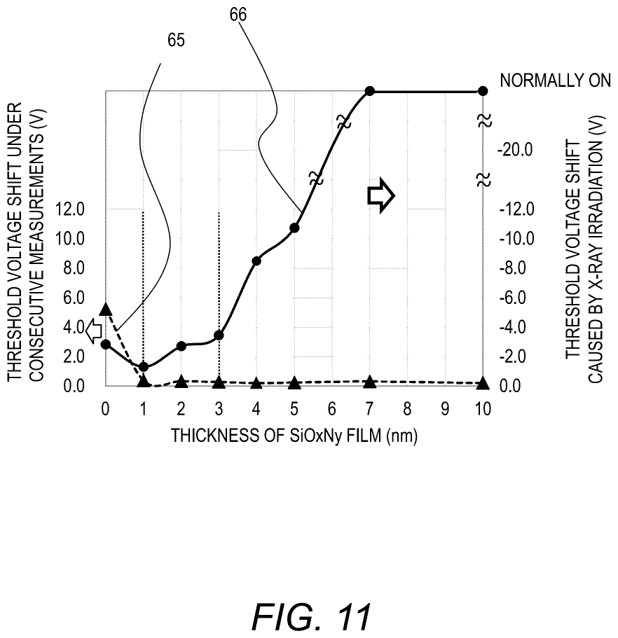

FIG. 11 is a graph in which the measurement results in FIGS. 9 and 10 are consolidated. The horizontal axis represents the thickness of the silicon oxynitride film. The left vertical axis represents the amount of the threshold voltage shift caused by application of gate voltage described with reference to FIG. 9. The right vertical axis represents the amount of the threshold voltage shift caused by X-ray irradiation described with reference to FIG. 10. The broken line 65 represents the variation in the amount of threshold voltage shift caused by the application of gate voltage and the solid line 66 represents the variation in the amount of threshold voltage shift caused by the X-ray irradiation.

As understood from the measurement results in FIGS. 9 to 11, a silicon oxynitride film having a thickness in the range from 1 nm to 3 nm can suppress the threshold voltage shift caused by gate voltage application and X-ray irradiation to the level that substantially does not affect the operation of the oxide semiconductor transistor.

### SECOND EMBODIMENT

The inventors' research revealed that the important for the silicon oxynitride film to work as an electron blocking layer is its composition. A silicon oxynitride film having a specific composition can reduce the effect of radioactive rays on the threshold voltage while preventing electrons from moving from the oxide semiconductor layer to the silicon nitride film. Regarding the structure of the switching thin-film transistor, the description provided with reference to FIGS. 4 and 5 is applicable except that the electron blocking layer is made of silicon oxynitride, instead of silicon oxide.

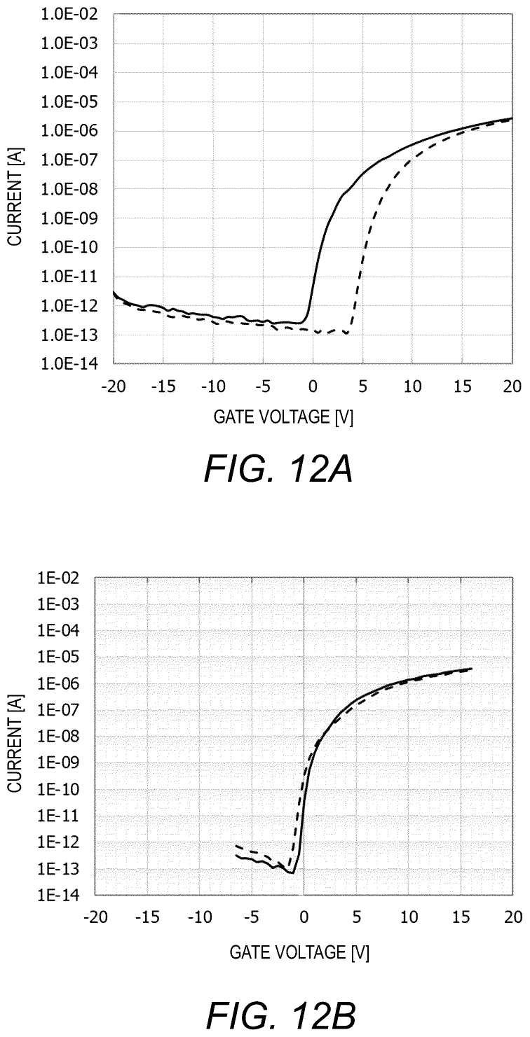

FIGS. 12A and 12B show changes in a characteristic of an oxide semiconductor transistor including an electron blocking layer made of a silicon oxynitride film having a first composition ratio. The layered structure of the oxide semiconductor transistor is as illustrated in FIGS. 4 and 5.

FIG. 12A shows measurement results on the change in IV characteristic between before and after gate voltage application. The horizontal axis represents gate voltage and the vertical axis represents drain current. The solid line indicates the variation in drain current caused by the first sweep of gate voltage and the broken line indicates the variation in drain current caused by the second sweep of gate voltage. As indicated in FIG. 12A, the second measurement result is significantly different from the first measurement result. Specifically, the gate voltage application causes a large threshold voltage shift. This shift is explained by the description about silicon nitride.

FIG. 12B shows measurement results on the change in IV characteristic between before and after X-ray irradiation. The horizontal axis represents gate voltage and the vertical axis represents drain current. The solid line indicates the measurement result before the X-ray irradiation and the broken line indicates the measurement result after the X-ray irradiation. As understood from the measurement results in FIG. 12B, there is no significant change in the characteristic between before and after the X-ray irradiation.

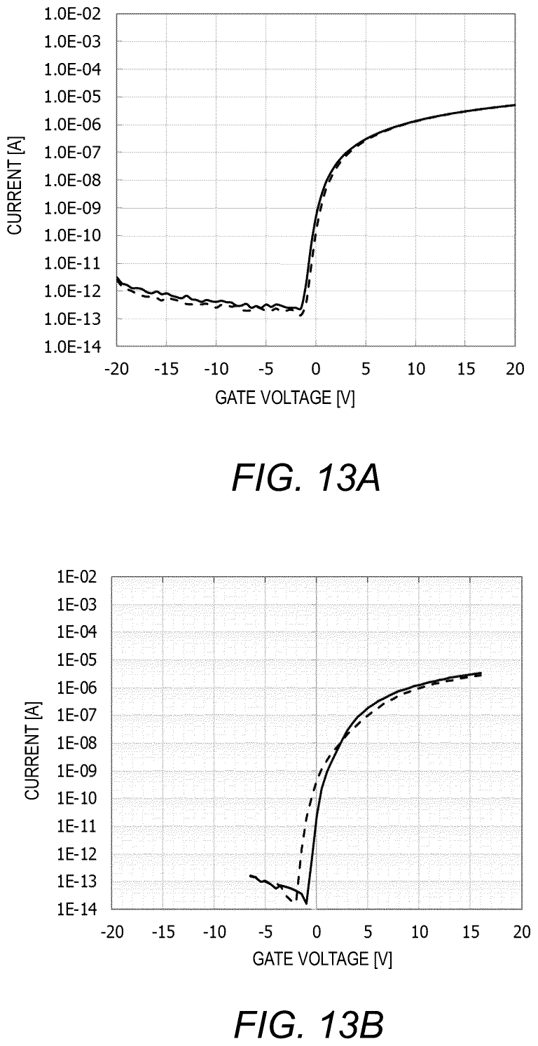

Next, changes in the characteristic of an oxide semiconductor transistor including an electron blocking layer made of a silicon oxynitride film having a second composition ratio that is different from the first composition ratio are shown. FIGS. 13A and 13B show changes in a characteristic of an oxide semiconductor transistor including a silicon oxynitride film having a second composition ratio. The layered structure of the oxide semiconductor transistor is as illustrated in FIGS. 4 and 5.

FIG. 13A shows measurement results on the change in IV characteristic between before and after gate voltage application. The horizontal axis represents gate voltage and the vertical axis represents drain current. The solid line indicates the variation in drain current caused by the first sweep of gate voltage and the broken line indicates the variation in drain current caused by the second sweep of gate voltage. As indicated in FIG. 13A, there is no significant change in the characteristic between the first measurement result and the second measurement result.

FIG. 13B shows measurement results on the change in IV characteristic between before and after X-ray irradiation. The horizontal axis represents gate voltage and the vertical axis represents drain current. The solid line indicates the measurement result before the X-ray irradiation and the broken line indicates the measurement result after the X-ray irradiation. As understood from the measurement results in FIG. 13B, there is no significant change in the characteristic between before and after the X-ray irradiation.

The above description explains that the silicon oxynitride film having the second composition ratio effectively functions as an electron blocking layer and suppresses the threshold voltage shift of the oxide semiconductor transistor caused by X-ray irradiation.

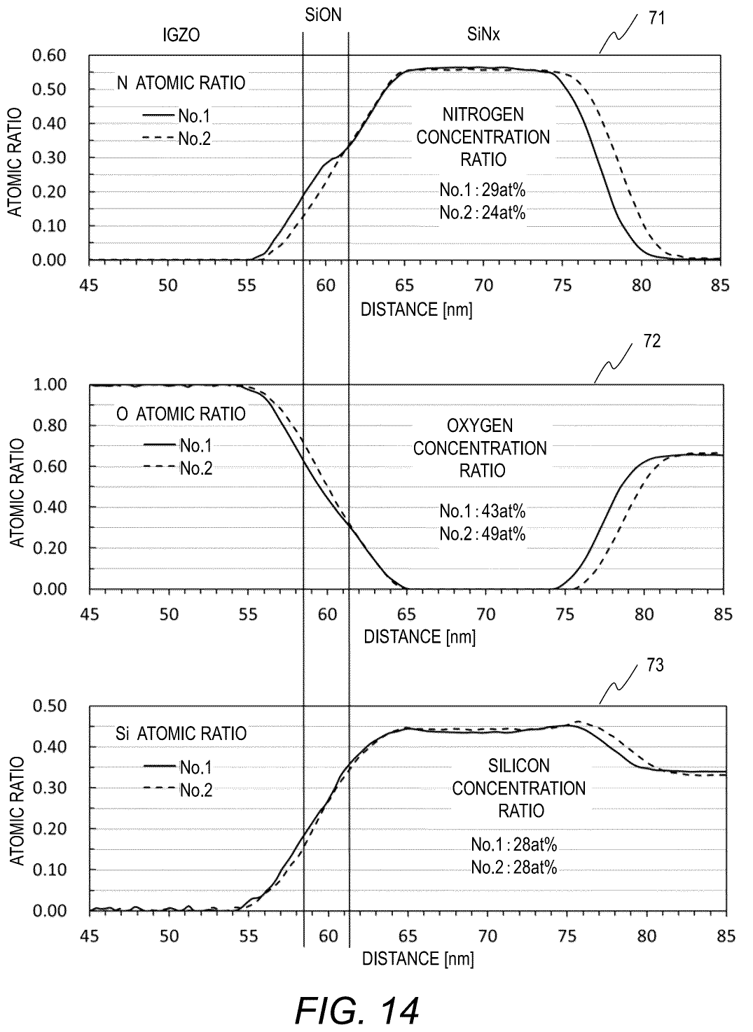

FIG. 14 provides results of composition analysis of an oxide semiconductor transistor including an electron blocking layer having the first composition ratio and an oxide semiconductor transistor including an electron blocking layer having the second composition ratio. The measurement was made by electron energy loss spectroscopy (EELS). FIG. 14 provides a graph 71 of the nitrogen concentration ratio, a graph 72 of the oxygen concentration ratio, and a graph 73 of the silicon concentration ratio.

In each graph, the horizontal axis represents the distance from the top face of the oxide semiconductor (IGZO) layer and the vertical axis represents the concentration ratio (atomic ratio) of the specific element. In each graph, the solid line indicates the measurement result of the oxide semiconductor transistor including a silicon oxynitride film having the first composition ratio and the broken line indicates the measurement result of the oxide semiconductor transistor including a silicon oxynitride film having the second composition ratio.

As indicated in FIG. 14, the silicon oxynitride (SiOxNy) films had a thickness of 3 nm. In the silicon oxynitride film having the first composition ratio, the nitrogen concentration ratio (29 at %) was higher than the silicon concentration ratio (28 at %). In the silicon oxynitride film having the second composition ratio, however, the nitrogen concentration ratio (24 at %) was lower than the silicon concentration ratio (28 at %). Configuring the electron blocking layer with a silicon oxynitride film having a nitrogen atomic ratio lower than the silicon atomic ratio as described above can effectively suppress the change in the characteristic of the oxide semiconductor transistor caused by gate voltage application and X-ray irradiation.

The silicon oxynitride film can be produced by annealing a silicon nitride film. For example, the annealing is conducted at 400° C. for one hour after depositing an oxide semiconductor layer (IGZO layer) on the silicon nitride film and patterning the IGZO layer. The annealing can be performed in the atmosphere. A thin silicon oxynitride film can be produced within the silicon nitride film with the oxygen from the oxide semiconductor layer.

### THIRD EMBODIMENT

Hereinafter, other configuration examples of the oxide semiconductor transistor related to the embodiments of this specification are described.

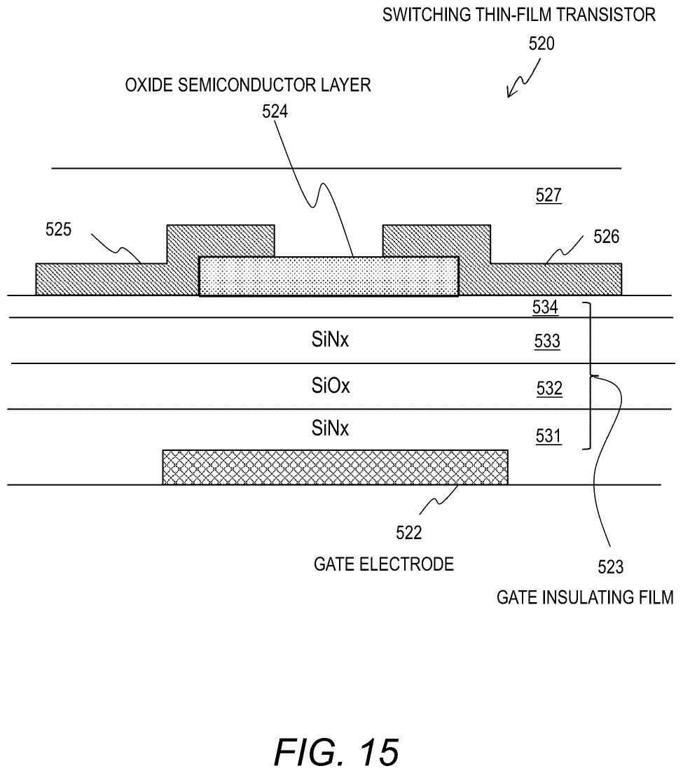

FIG. 15 is a cross-sectional diagram schematically illustrating a structural example of a switching thin-film transistor in an X-ray sensor in an embodiment of this specification. The switching thin-film transistor 520 includes a gate electrode 522, a gate insulating film 523 above the gate electrode 522, and an oxide semiconductor layer 524 above the gate insulating film 523. An interlayer insulating film 527 covers the entire switching thin-film transistor 520. Although the thin-film transistor 520 in this embodiment is of a channel etch type, it can be of a channel protection type such that the channel region of the oxide semiconductor layer 524 is protected with an insulating film.

The gate insulating film 523 has a four-layer structure consisting of a lower silicon nitride (SiNx) film 531, a silicon oxide (SiOx) film 532 above the lower silicon nitride film 531, an upper silicon nitride film 533 above the silicon oxide film 532, and another silicon oxide film 534 above the upper silicon nitride film 533.

The silicon oxide film 534 is in direct contact with the upper silicon nitride film 533 and the oxide semiconductor layer 524 and has interfaces with them. The silicon oxide film 534 has a thickness not less than 1 nm and not more than 4 nm and functions as an electron blocking layer for the electrons from the oxide semiconductor layer 524 to the upper silicon nitride film 533. The silicon oxide film 534 can be thinner than any of the lower silicon nitride film 531, the silicon oxide film 532, and the upper silicon nitride film 533. The silicon oxide film 534 as an electron blocking layer can be replaced with the silicon oxynitride film in the first or second embodiment. The description about the electron blocking layer in the first or second embodiment is applicable to this configuration example.

The silicon oxide film 532 is in direct contact with the lower silicon nitride film 531 and the upper silicon nitride film 533 and has interfaces with them. The lower silicon nitride film 531 has an interface with the gate electrode 522. The upper and lower silicon nitride films 531 and 533 sandwiching the silicon oxide film 532 reduce the effect of the silicon oxide film 532 onto the threshold voltage caused by X-ray irradiation.

The switching thin-film transistor 520 has a bottom-gate structure; the gate electrode 522 is located under the oxide semiconductor layer 524. The switching thin-film transistor 520 further includes a source/drain electrode 525 and another source/drain electrode 526 above the gate insulating film 523. The source/drain electrodes 525 and 526 are individually connected to the oxide semiconductor layer 524. The description about the components provided with reference to FIG. 3 or 4 is applicable to the gate electrode 522, the source/drain electrodes 525 and 526, and the interlayer insulating film 527.

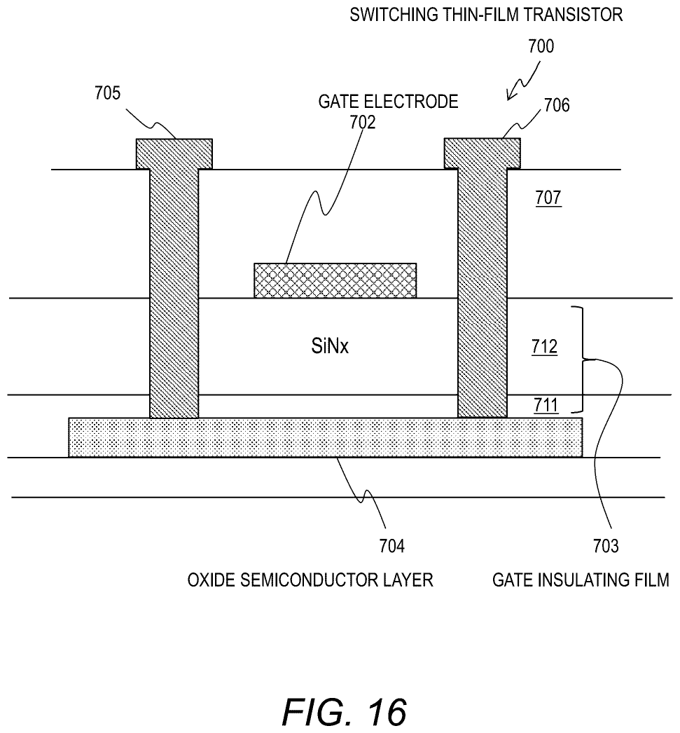

FIG. 16 is a cross-sectional diagram illustrating a structural example of a switching thin-film transistor having a top-gate structure. The switching thin-film transistor 700 includes an oxide semiconductor layer 704, a gate insulating film 703 above the oxide semiconductor layer 704, and a gate electrode 702 above the gate insulating film 703. The gate insulating film 703 has a two-layer structure consisting of a silicon oxide (SiOx) film 711 and a silicon nitride (SiNx) film 712 above the silicon oxide film 711.

The silicon nitride film 712 is in direct contact with the gate electrode 702 and the silicon oxide film 711 and has interfaces with them. The silicon oxide film 711 is in direct contact with the oxide semiconductor layer 704 and the silicon nitride film 712 and has interfaces with them.

The silicon oxide film 711 has a thickness not less than 1 nm and not more than 4 nm and functions as an electron blocking layer for the electrons from the oxide semiconductor layer 704 to the silicon nitride film 712. The silicon oxide film 711 is thinner than the silicon nitride film 712. The silicon oxide film 711 as an electron blocking layer can be replaced with the silicon oxynitride film in the first or second embodiment. The description about the electron blocking layer in the first or second embodiment is applicable to this configuration example.

The silicon nitride film 712 can be replaced with an insulating film having a three-layer structure consisting of upper and lower silicon nitride films and a silicon oxide film therebetween, as described with reference to FIG. 15. The silicon oxide film 711 can be thinner than any of the layers constituting the three-layer insulating film.

The switching thin-film transistor 700 has a top-gate structure; the gate electrode 702 is located above the oxide semiconductor layer 704. The switching thin-film transistor 700 further includes a source/drain electrode 705 and another source/drain electrode 706. Each of the source/drain electrodes 705 and 706 extends through the interlayer insulating film 707 and the gate insulating film 703 to be connected to the oxide semiconductor layer 704. The foregoing description about the thin-film transistor having a bottom-gate structure is applicable to the gate insulating film 703 and the description provided with reference to FIG. 3 or 4 is applicable to the gate electrode 702, the source/drain electrodes 705 and 706, and the interlayer insulating film 707.

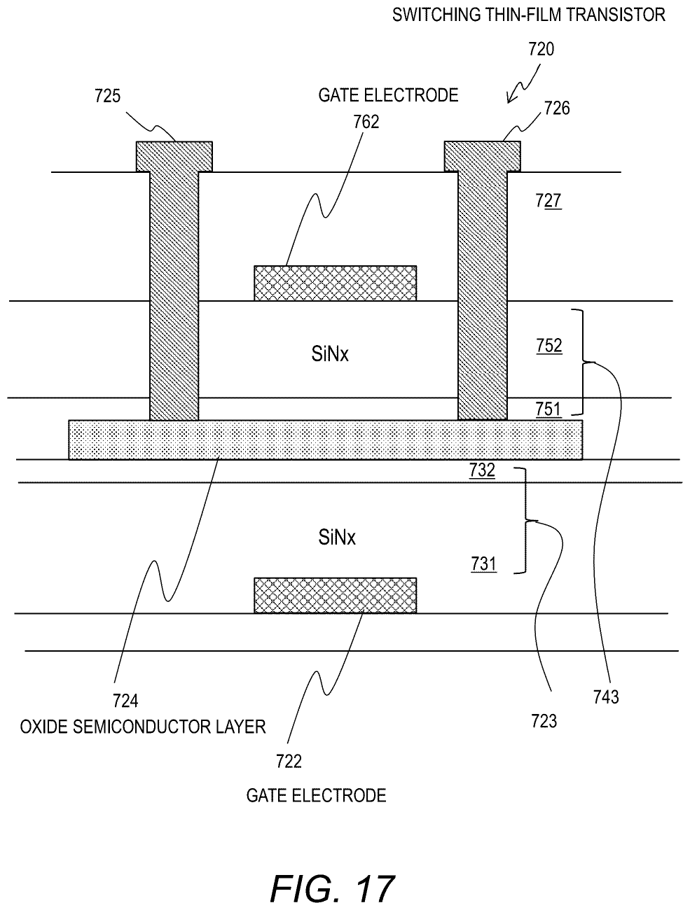

FIG. 17 is a cross-sectional diagram illustrating a structural example of a switching thin-film transistor having a dual-gate structure. The switching thin-film transistor 720 includes a gate electrode 722, a gate insulating film 723 above the gate electrode 722, and an oxide semiconductor layer 724. The switching thin-film transistor 720 further includes another gate insulating film 743 above the oxide semiconductor layer 724 and another gate electrode 762 above the gate insulating film 743.

The gate insulating film 723 has a two-layer structure consisting of a silicon nitride film 731 and a silicon oxide film 732 above the silicon nitride film 731. The silicon oxide film 732 is in direct contact with the silicon nitride film 731 and the oxide semiconductor layer 724 and has interfaces with them. The silicon nitride film 731 is in direct contact with the gate electrode 722 and the silicon oxide film 732 and has interfaces with them.

The gate insulating film 743 has a two-layer structure consisting of a silicon oxide film 751 and a silicon nitride film 752 above the silicon oxide film 751. The silicon oxide film 751 is in direct contact with the oxide semiconductor layer 724 and the silicon nitride film 752 and has interfaces with them. The silicon nitride film 752 is in direct contact with the silicon oxide film 751 and the gate electrode 762 and has interfaces with them.

The switching thin-film transistor 720 has a dual-gate structure; the oxide semiconductor layer 724 is disposed between the top gate electrode 762 and the bottom gate electrode 722. The switching thin-film transistor 720 further includes a source/drain electrode 725 and another source/drain electrode 726. Each of the source/drain electrodes 725 and 726 extends through the interlayer insulating film 727 and the gate insulating film 743 to be connected to the oxide semiconductor layer 724.

The description about the gate insulating film in the bottom gate structure provided with reference to FIG. 5 or 15 is applicable to the gate insulating film 723. Specifically, the silicon oxide film 732 has a thickness not less than 1 nm and not more than 4 nm and functions as an electron blocking layer for the electrons from the oxide semiconductor layer 724 to the silicon nitride film 731. The silicon oxide film 732 is thinner than the silicon nitride film 731. The silicon oxide film 732 as an electron blocking layer can be replaced with the silicon oxynitride film in the first or second embodiment. The description about the electron blocking layer in the first or second embodiment is applicable to this configuration example.

The silicon nitride film 731 can be replaced with an insulating film having a three-layer structure consisting of upper and lower silicon nitride films and a silicon oxide film therebetween, as described with reference to FIG. 15. The silicon oxide film 732 can be thinner than any of the layers constituting the three-layer insulating film. The description about the gate insulating film in the top gate structure provided

with reference to FIG. 16 is applicable to the gate insulating film 743. Specifically, the silicon oxide film 751 has a thickness not less than 1 nm and not more than 4 nm and functions as an electron blocking layer for the electrons from the oxide semiconductor layer 724 to the silicon nitride film 752. The silicon oxide film 751 is thinner than the silicon nitride film 752. The silicon oxide film 751 as an electron blocking layer can be replaced with the silicon oxynitride film in the first or second embodiment. The description about the electron blocking layer in the first or second embodiment is applicable to this configuration example.

The silicon nitride film 752 can be replaced with an insulating film having a three-layer structure consisting of upper and lower silicon nitride films and a silicon oxide film therebetween, as described with reference to FIG. 15. The silicon oxide film 751 can be thinner than any of the layers constituting the three-layer insulating film.

The gate insulating films 723 and 743 can have the same configuration or different configurations. The description about the components provided with reference to FIG. 3 or 4 is applicable to the gate electrodes 722 and 762, the source/drain electrodes 725 and 726, and the interlayer insulating film 727.

As set forth above, embodiments of this disclosure have been described; however, this disclosure is not limited to the foregoing embodiments. Those skilled in the art can easily modify, add, or convert each element in the foregoing embodiments within the scope of this disclosure. A part of the configuration of one embodiment can be replaced with a configuration of another embodiment or a configuration of an embodiment can be incorporated into a configuration of another embodiment.

What is claimed is:

1. A thin-film transistor to be used for a radiation sensor, the thin-film transistor comprising:
a gate electrode;
an oxide semiconductor layer; and
a gate insulating film located between the oxide semiconductor layer and the gate electrode,
wherein the gate insulating film includes:
a silicon nitride layer; and
a silicon oxide layer located between the silicon nitride layer and the oxide semiconductor layer and having interfaces with the silicon nitride layer and the oxide semiconductor layer, and
wherein the silicon oxide layer has a thickness not less than 1 nm and not more than 4 nm.

2. The thin-film transistor according to claim 1,
wherein the silicon nitride layer is a first silicon nitride layer,
wherein the gate insulating film further includes:
a second silicon nitride layer located between the gate electrode and the first silicon nitride layer; and
a second silicon oxide layer located between the second silicon nitride layer and the first silicon nitride layer,
wherein the second silicon oxide layer has interfaces with the second silicon nitride layer and the first silicon nitride layer, and
wherein the second silicon nitride layer has an interface with the gate electrode.

3. The thin-film transistor according to claim 1, wherein the gate electrode is located between a substrate and the oxide semiconductor layer.

4. A radiation sensor comprising:
a substrate;
a photoelectric conversion element on the substrate;
the thin-film transistor according to claim 1 located between the substrate and the photoelectric conversion element; and
a signal line,
wherein the thin-film transistor is configured to switch between connection and disconnection of the signal line and the photoelectric conversion element.

5. A thin-film transistor to be used for a radiation sensor, the thin-film transistor comprising:
a gate electrode;
an oxide semiconductor layer; and
a gate insulating film located between the oxide semiconductor layer and the gate electrode,
wherein the gate insulating film includes:
a silicon nitride layer; and
a silicon oxynitride layer located between the silicon nitride layer and the oxide semiconductor layer and having interfaces with the silicon nitride layer and the oxide semiconductor layer, and
wherein the silicon oxynitride layer has a thickness not less than 1 nm and not more than 3 nm.

6. The thin-film transistor according to claim 5,
wherein the silicon nitride layer is a first silicon nitride layer,
wherein the gate insulating film further includes:
a second silicon nitride layer located between the gate electrode and the first silicon nitride layer; and
a second silicon oxide layer located between the second silicon nitride layer and the first silicon nitride layer,
wherein the second silicon oxide layer has interfaces with the second silicon nitride layer and the first silicon nitride layer, and
wherein the second silicon nitride layer has an interface with the gate electrode.

7. The thin-film transistor according to claim 5, wherein the gate electrode is located between a substrate and the oxide semiconductor layer.

8. A radiation sensor comprising:
a substrate;
a photoelectric conversion element on the substrate;
the thin-film transistor according to claim 5 located between the substrate and the photoelectric conversion element; and
a signal line,
wherein the thin-film transistor is configured to switch between connection and disconnection of the signal line and the photoelectric conversion element.

9. A thin-film transistor to be used for a radiation sensor, the thin-film transistor comprising:
a gate electrode;
an oxide semiconductor layer; and
a gate insulating film located between the oxide semiconductor layer and the gate electrode,
wherein the gate insulating film includes:
a silicon nitride layer; and
a silicon oxynitride layer located between the silicon nitride layer and the oxide semiconductor layer and having interfaces with the silicon nitride layer and the oxide semiconductor layer, and
wherein the silicon oxynitride layer has a nitrogen atomic ratio lower than a silicon atomic ratio.

10. The thin-film transistor according to claim 9,
wherein the silicon nitride layer is a first silicon nitride layer,
wherein the gate insulating film further includes:
a second silicon nitride layer located between the gate electrode and the first silicon nitride layer; and
a second silicon oxide layer located between the second silicon nitride layer and the first silicon nitride layer,
wherein the second silicon oxide layer has interfaces with the second silicon nitride layer and the first silicon nitride layer, and
wherein the second silicon nitride layer has an interface with the gate electrode.

11. The thin-film transistor according to claim 9, wherein the gate electrode is located between a substrate and the oxide semiconductor layer.

12. A radiation sensor comprising:
a substrate;
a photoelectric conversion element on the substrate;
the thin-film transistor according to claim 9 located between the substrate and the photoelectric conversion element; and
a signal line,
wherein the thin-film transistor is configured to switch between connection and disconnection of the signal line and the photoelectric conversion element.
